(19) United States
(12) Patent Application Publication
(10) Pub. No.: US 2022/0301504 A1
(43) Pub. Date: Sep. 22, 2022

(54) PIXEL CIRCUIT AND DISPLAY DEVICE

(71) Applicant: WUHAN CHINA STAR OPTOELECTRONICS SEMICONDUCTOR DISPLAY TECHNOLOGY CO., LTD., Wuhan (CN)

(72) Inventors: Xuanyun Wang, Wuhan (CN); Sunghwan Cho, Wuhan (CN); Chao Dai, Wuhan (CN)

(73) Assignee: WUHAN CHINA STAR OPTOELECTRONICS SEMICONDUCTOR DISPLAY TECHNOLOGY CO., LTD., Wuhan (CN)

(21) Appl. No.: 17/262,668

(22) PCT Filed: Aug. 20, 2020
(86) PCT No.: PCT/CN2020/110213

§ 371 Date: Jan. 22, 2021

(30) Foreign Application Priority Data
Jul. 14, 2020 (CN) 202010676996.3

(51) Int. Cl. G09G 3/3233; H01L 27/32

(52) U.S. Cl. CPC G09G 3/3233; H01L 27/3262; G09G 2320/045; G09G 2300/0842; H01L 27/1225

(57) ABSTRACT

A pixel circuit and a display device are provided. The pixel circuit includes a light emitting control unit, a reset unit, a compensation unit, and an initialization unit. The light emitting control unit is disposed between a first power source signal input terminal and a light emitting unit. The reset unit is disposed between a reset signal input terminal and the light emitting unit. The light emitting control unit and the reset unit are electrically connected to a control signal input terminal. The compensation unit and the initialization unit include metal-oxide transistors.

### CROSS REFERENCE TO RELATED APPLICATIONS

This application claims priority of Chinese patent Application No. CN202010676996.3 filed on Jul. 14, 2020 with the National Intellectual Property Administration, titled “PIXEL CIRCUIT AND DISPLAY DEVICE”, which is incorporated by reference in the present application in its entirety.

### FIELD OF INVENTION

The present disclosure relates to a field of display technology, and particularly to a pixel circuit and a display device.

### BACKGROUND OF INVENTION

With development of multimedia, display devices are increasingly important. Correspondingly, requirements on various display devices are increasingly higher. Especially, in the field of intelligent mobile phones, ultrahigh frequency driving display, low power consumption driving display, and low frequency driving display are important development trends in present and future.

Display function realized on display devices is inseparable from driving of pixel circuits. The pixel circuits act as important components for driving light emitting units of the display devices to emit light, and stability and sensitivity of their working performance directly affect display effect of the display devices. The pixel circuits include a plurality of transistor components, wherein common transistor types are amorphous silicon (a-Si) transistors, low-temperature polycrystalline-silicon (LTPS) thin film transistors, and metal-oxide semiconductor thin film transistors. Furthermore, the amorphous silicon transistors and the low-temperature polycrystalline-silicon thin film transistors are silicon-based thin film transistors, having advantages of fast switching speed and large driving current, but are prone to generate larger leakage current, while the metal-oxide thin film transistors have advantages of small leakage current, good uniformity, etc.

In current designs of the pixel circuits, there are two problems that are prone to appear, one is larger leakage current exists at control terminals of driving transistors of the pixel circuits, resulting in light emitting units abnormally emitting light and causing a splash screen problem to occur on the display devices; another is a problem of poor picture quality of the display devices in a dark state incurred by transistors configured to drive anodes to reset in the pixel circuit not turning on immediately or having overly short turning on time.

### SUMMARY OF INVENTION

In order to solve the technical problems mentioned above, the present disclosure provides the following solutions.

The present disclosure provides a pixel circuit, including:

a light emitting control unit disposed between a first power source signal input terminal and a light emitting unit and electrically connected to a control signal input terminal;

a reset unit disposed between a reset signal input terminal and the light emitting unit and electrically connected to the control signal input terminal;

a compensation unit electrically connected to a first scanning signal input terminal; and

an initialization unit electrically connected to a second scanning signal input terminal,

wherein the compensation unit and the initialization unit include metal-oxide transistors.

In the pixel circuit of the present disclosure, a control terminal of the light emitting control unit is electrically connected to the control signal input terminal and realizes switch between turning on and turning off states of the light emitting control unit under effect of signals output from the control signal input terminal.

In the pixel circuit of the present disclosure, a control terminal of the reset unit is electrically connected to the control signal input terminal and realizes switch between turning on and turning off states of the reset unit under effect of signals output from the control signal input terminal.

In the pixel circuit of the present disclosure, the reset unit includes a metal-oxide transistor.

In the pixel circuit of the present disclosure, the light emitting control unit includes a low-temperature polycrystalline-silicon transistor.

In the pixel circuit of the present disclosure, the light emitting control unit includes a first light emitting control unit and a second light emitting control unit, and the first light emitting control unit and the second light emitting control unit are electrically connected to the control signal input terminal.

In the pixel circuit of the present disclosure, the first light emitting control unit and the second light emitting control unit include metal-oxide transistors.

In the pixel circuit of the present disclosure, the reset unit includes a low-temperature polycrystalline-silicon transistor.

In the pixel circuit of the present disclosure, the control signal input terminal includes a first control signal input terminal and a second control signal input terminal.

In the pixel circuit of the present disclosure, the first light emitting control unit is electrically connected to the first control signal input terminal, and the second light emitting control unit and the reset unit are electrically connected to the second control signal input terminal.

In the pixel circuit of the present disclosure, the first light emitting control unit and the reset unit include metal-oxide transistors.

In the pixel circuit of the present disclosure, the second light emitting control unit includes a low-temperature polycrystalline-silicon transistor.

In the pixel circuit of the present disclosure, the first light emitting control unit and the reset unit are electrically connected to the first control signal input terminal, and the second light emitting control unit is electrically connected to the second control signal input terminal.

In the pixel circuit of the present disclosure, the first light emitting control unit and the second light emitting control unit include metal-oxide transistors.

In the pixel circuit of the present disclosure, the reset unit includes a low-temperature polycrystalline-silicon transistor.

In the present disclosure, the pixel circuit further includes:

a data signal transmission unit disposed between a data signal input terminal and the light emitting control unit;

a driving unit disposed between the first light emitting control unit and the second light emitting control unit; and

a storage unit disposed between the first power source signal input terminal and the driving unit.

According to one embodiment of the present disclosure, the first light emitting control unit includes a fifth transistor, a gate electrode of the fifth transistor is electrically connected to the control signal input terminal, a source electrode of the fifth transistor is electrically connected to the first power source signal input terminal, and a drain electrode of the fifth transistor is electrically connected to a first node;

the second light emitting control unit includes a sixth transistor, a gate electrode of the sixth transistor is electrically connected to the control signal input terminal, a source electrode of the sixth transistor is electrically connected to a second node, and a drain electrode of the sixth transistor is electrically connected to the light emitting unit;

the reset unit includes a seventh transistor, a gate electrode of the seventh transistor is electrically connected to the control signal input terminal, a source electrode of the seventh transistor is electrically connected to the reset signal input terminal, and a drain electrode of the seventh transistor is electrically connected to the light emitting unit;

the compensation unit includes a third transistor, a gate electrode of the third transistor is electrically connected to the first scanning signal input terminal, a source electrode of the third transistor is electrically connected to the second node, and a drain electrode of the third transistor is electrically connected to a third node;

the initialization unit includes a fourth transistor, a gate electrode of the fourth transistor is electrically connected to the second scanning signal input terminal, a source electrode of the fourth transistor is electrically connected to the reset signal input terminal, and a drain electrode of the fourth transistor is electrically connected to the third node;

the data signal transmission unit includes a second transistor, a gate electrode of the second transistor is electrically connected to a third scanning signal input terminal, a source electrode of the second transistor is electrically connected to the data signal input terminal, and a drain electrode of the second transistor is electrically connected to the first node;

the driving unit includes a first transistor, a gate electrode of the first transistor is electrically connected to the third node, a source electrode of the first transistor is electrically connected to the first node, and a drain electrode of the first transistor is electrically connected to the second node; and

the storage unit includes a storage capacitor, a first electrode of the storage capacitor is electrically connected to the first power source signal input terminal, and a second electrode of the storage capacitor is electrically connected to the third node.

The present disclosure further provides a display device, including a pixel circuit. The pixel circuit includes:

a light emitting control unit disposed between a first power source signal input terminal and a light emitting unit and electrically connected to a control signal input terminal;

a reset unit disposed between a reset signal input terminal and the light emitting unit and electrically connected to the control signal input terminal;

a compensation unit electrically connected to a first scanning signal input terminal; and

an initialization unit electrically connected to a second scanning signal input terminal,

wherein the compensation unit and the initialization unit comprise metal-oxide transistors.

In the display device of the present disclosure, the reset unit includes a metal-oxide transistor, and the light emitting control unit includes a low-temperature polycrystalline-silicon transistor.

In the display device of the present disclosure, the reset unit includes a low-temperature polycrystalline-silicon transistor, and the light emitting control unit includes a metal-oxide transistor.

In the pixel circuit and the display device provided by the present disclosure, by electrically connecting the reset unit of the pixel circuit to the control signal input terminal directly, and by utilizing the signal output by the control signal input terminal to control turning on of the reset unit, a reset time of the light emitting unit is increased, and the picture quality of the display device is improved. Meanwhile, disposing metal-oxide transistors in the compensation unit and the initialization unit of the pixel circuit makes the leakage current in the circuit and the splash screen problem incurred by the leakage current obtain significant relievement.

### DESCRIPTION OF DRAWINGS

To more clearly illustrate embodiments or the technical solutions of the present disclosure, the accompanying figures of the present disclosure required for illustrating embodiments or the technical solutions of the present disclosure will be described in brief. Obviously, the accompanying figures described below are only part of the embodiments of the present disclosure, from which those skilled in the art can derive further without making any inventive efforts.

FIG. 1 is a structural schematic diagram of a first embodiment of a pixel circuit provided by one embodiment of the present disclosure.

FIG. 2 is a structural schematic diagram of a second embodiment of the pixel circuit provided by one embodiment of the present disclosure.

FIG. 3 is a structural schematic diagram of a third embodiment of the pixel circuit provided by one embodiment of the present disclosure.

FIG. 4 is a structural schematic diagram of a fourth embodiment of the pixel circuit provided by one embodiment of the present disclosure.

FIG. 5 is a sectional structural schematic diagram of an organic light emitting diode display device including a low-temperature polycrystalline-silicon transistor and a metal-oxide transistor provided by one embodiment of the present disclosure.

### DETAILED DESCRIPTION OF PREFERRED EMBODIMENTS

The descriptions of embodiments below refer to accompanying drawings in order to illustrate certain embodiments which the present disclosure can implement. The directional terms of which the present disclosure mentions, for example, “top”, “bottom”, “upper” , “lower”, “front”, “rear”, “left”, “right”, “inside”, “outside”, “side”, etc., only refer to directions of the accompanying figures. Therefore, the used directional terms are for illustrating and understanding the present disclosure, but not for limiting the present disclosure. In the figures, units with similar structures are indicated by the same reference numerals.

Embodiments of the present disclosure provide a pixel circuit. By electrically connecting a reset unit and a reset unit of the pixel circuit to a control signal input terminal directly, and by utilizing an signal output by the control signal input terminal to control turning on of the reset unit, a reset time of a light emitting unit is increased, and picture quality of a display device is improved. Meanwhile, disposing metal-oxide transistors in a compensation unit and an initialization unit of the pixel circuit relieves leakage current in the circuit and a splash screen problem incurred by the leakage current.

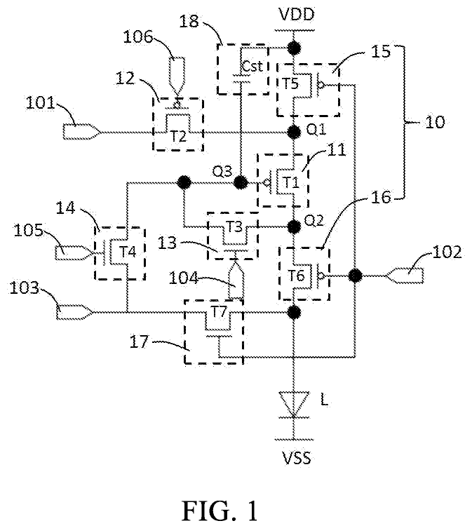

According to one embodiment of the present disclosure, FIG. 1 is a structural schematic diagram of a first embodiment of a pixel circuit provided by one embodiment of the present disclosure. The pixel circuit includes a light emitting control unit 10, a reset unit 17, a compensation unit 13, and an initialization unit 14.

The light emitting control unit 10 is disposed between a first power source signal input terminal VDD and a light emitting unit L. By controlling an electrically conducting state between the first power source signal input terminal VDD and the light emitting unit L, control of a light emitting time of the light emitting unit L is realized. For example, when the light emitting control unit 10 is in a turning on state, an electric current can flow to the light emitting unit L from the first power source signal input terminal VDD, then the light emitting unit L emits light, otherwise, the light emitting unit L does not emit light. The light emitting control unit 10 is electrically connected to a control signal input terminal 102. Under effect of signals output from the control signal input terminal 102, the light emitting control unit 10 realizes switch between turning on and turning off states.

The reset unit 17 is disposed between the reset signal input terminal 103 and the light emitting unit L and is configured to control an electrically conducting state between the reset signal input terminal 103 and the light emitting unit L. When the reset unit 17 is in the turning on state, the reset signal input terminal 103 and the light emitting unit L are directly electrically conductive. A reset signal output from the reset signal input terminal 103 is transmitted to the light emitting unit L, realizing a reset operation for the light emitting unit L. It should be understood that when the light emitting unit L turns from a light emitting state to a dark state, if some unstable electric current exists in the circuit, this will result in the light emitting unit L flashing abnormally. At this time, by transmitting the reset signal to the light emitting unit L to eliminate the unstable electric current, the light emitting unit L is made to be in the stable dark state, thereby improving the picture quality in the dark state.

Furthermore, the reset unit 17 is electrically connected to the control signal input terminal 102. The reset unit 17 realizes switch between turning on and turning off states under effect of signals output from the control signal input terminal 102. It should be noted that in traditional designs, the reset unit is turned on or turned off by control of scanning signals, at this time, a problem of not turning on immediately or overly short turning on time is prone to appear, resulting in poor picture quality in the dark state. In this embodiment, the reset unit 17 is controlled by the signal output by the control signal input terminal 102. While the control signal input terminal 102 controls the light emitting control unit 102 to turn off, the reset unit 17 is controlled to turn on, and the light emitting unit L is realized to reset immediately. Meanwhile, in an entire dark state time of the light emitting unit L, the reset unit 17 continuously maintains the turning on state, effectively eliminating flashing in the dark state and improving the picture quality in the dark state.

The compensation unit 13 is electrically connected to a first scanning signal input terminal 104. A scanning signal output from the first scanning signal input terminal 104 controls the compensation unit 13 to turn on or to turn off. The initialization unit 14 is electrically connected to the second scanning signal input terminal 105. A scanning signal output from the second scanning signal input terminal 105 controls the initialization unit 14 to turn on or to turn off. The compensation unit 13 and the initialization unit 14 include metal-oxide transistors. It should be noted that the metal-oxide transistors have advantage of low leakage of electricity. In this embodiment, by disposing the metal-oxide transistors in the compensation unit 13 and the initialization unit 14, the problem of the leakage current in the pixel circuit can be relieved significantly, thereby relieving the splash screen problem incurred by excessive leakage current.

Optionally, the reset unit 17 includes metal-oxide transistors to relieve the leakage current problem of the reset unit 17 itself, and further promotes relievement of the leakage current problem of the entire pixel circuit. Optionally, the light emitting control unit 10 includes low-temperature polycrystalline-silicon transistors.

It should be noted that in one embodiment of the present disclosure, the metal-oxide transistor means the transistor using metal oxide to act as a semiconductor material. The metal-oxide transistors can be a semiconductor material such as ZnO, ZTO, ZIO, InO, TiO, IGZO, or IZTO, etc. N-type transistors are usually used in the metal-oxide transistors, that is, they are conductive or turned on in high electric level effect, and are cut off or turned off in low electric level. In one embodiment of the present disclosure, the low-temperature polycrystalline-silicon transistor means a transistor using polycrystalline silicon to act as a semiconductor material. P-type transistors are usually used as the low-temperature polycrystalline-silicon transistor, that is, they are conductive or turned on in low electric level effect, and are cut off or turned off in high electric level.

Optionally, the light emitting control unit 10 includes a first light emitting control unit 15 and a second light emitting control unit 16, and the first light emitting control unit 15, the second light emitting control unit 16, and the reset unit 17 are electrically connected to the control signal input terminal 102. Optionally, the first light emitting control unit 15 and the second light emitting control unit 16 include low-temperature polycrystalline-silicon transistors using the P-type transistors, and the reset unit 17 includes the metal-oxide transistor using the N-type transistors. By the configuration mentioned above, the reset unit 17 can be ensured to be in the turning off state when the first light emitting control unit 15 and the second light emitting control unit 16 are in the turning on state. On the contrary, the reset unit 17 is in the turning on state when the first light emitting control unit 15 and the second light emitting control unit 16 are in the turning off state, thereby making turning on time periods of the reset unit 17 always correspond to dark state periods of the light emitting unit L.

Furthermore, the pixel circuit further includes a data signal transmission unit 12, a driving unit 11, and a storage unit 18. The data signal transmission unit 12 is disposed between the data signal input terminal 101 and the light emitting control unit 10 to control electrically conducting state between the data signal input terminal 101 and the light emitting control unit 10. Optionally, the data signal transmission unit 12 is further electrically connected to a third scanning signal input terminal 106. The third scanning signal input terminal 106 outputs scanning signals to control the data signal transmission unit 12 to turn on or to turn off. The driving unit 11 is disposed between the first light emitting control unit 15 and the second light emitting control unit 16 to control electrically conducting state between the first light emitting control unit 15 and the second light emitting control unit 16. The storage unit 18 is disposed between the first power source signal input terminal VDD and the driving unit 11 to store a voltage state of a control terminal of the driving unit 11.

Optionally, the first light emitting control unit 15 includes a fifth transistor T5. A gate electrode of the fifth transistor T5 is electrically connected to the control signal input terminal 102. A source electrode of the fifth transistor T5 is electrically connected to the first power source signal input terminal VDD. A drain electrode of the fifth transistor T5 is electrically connected to a first node Q1. Optionally, the fifth transistor T5 is the low-temperature polycrystalline-silicon transistor.

Optionally, the second light emitting control unit 16 includes a sixth transistor T6. A gate electrode of the sixth transistor T6 is electrically connected to the control signal input terminal 102. A source electrode of the sixth transistor T6 is electrically connected to a second node Q2. A drain electrode of the sixth transistor T6 is electrically connected to the light emitting unit L. Another end of the light emitting unit L is electrically connected to a second power source signal input terminal VSS. Optionally, a voltage input into the first power source signal input terminal VDD is greater than a voltage input into the second power source signal input terminal VSS. Optionally, the sixth transistor T6 is the low-temperature polycrystalline-silicon transistor.

Optionally, the reset unit 17 includes a seventh transistor T7. A gate electrode of the seventh transistor T7 is electrically connected to the control signal input terminal 102. A source electrode of the seventh transistor T7 is electrically connected to the reset signal input terminal 103. A drain electrode of the seventh transistor T7 is electrically connected to the light emitting unit L. Optionally, the seventh transistor T7 is the metal-oxide transistor.

Optionally, the compensation unit 13 includes a third transistor T3. A gate electrode of the third transistor T3 is electrically connected to the first scanning signal input terminal 104. A source electrode of the third transistor T3 is electrically connected to the second node Q2. A drain electrode of the third transistor T3 is electrically connected to a third node Q3. Optionally, the third transistor T3 is the metal-oxide transistor.

Optionally, the initialization unit 14 includes a fourth transistor T4. A gate electrode of the fourth transistor T4 is electrically connected to the second scanning signal input terminal 105. A source electrode of the fourth transistor T4 is electrically connected to the reset signal input terminal 103. A drain electrode of the fourth transistor T4 is electrically connected to the third node Q3. Optionally, the fourth transistor T4 is the metal-oxide transistor.

Optionally, the data signal transmission unit 12 includes a second transistor T2. A gate electrode of the second transistor T2 is electrically connected to a third scanning signal input terminal 106. A source electrode of the second transistor T2 is electrically connected to the data signal input terminal 101. A drain electrode of the second transistor T2 is electrically connected to the first node Q1.

Optionally, the driving unit 11 includes a first transistor T1. A gate electrode of the first transistor T1 is electrically connected to the third node Q3. A source electrode of the first transistor T1 is electrically connected to the first node Q1. A drain electrode of the first transistor T1 is electrically connected to the second node Q2.

Optionally, the storage unit 18 includes a storage capacitor Cst. A first electrode of the storage capacitor Cst is electrically connected to the first power source signal input terminal VDD, and a second electrode of the storage capacitor Cst is electrically connected to the third node Q3. The storage capacitor Cst is configured to store a threshold voltage of the first transistor T1.

Optionally, the first scanning signal input terminal 104, the second scanning signal input terminal 105, and the third scanning signal input terminal 106 are respectively electrically connected to different scanning signal lines. It should be understood that the display device can include a plurality of stages of pixel circuits mentioned in this embodiment. The first scanning signal input terminal 104 and the third scanning signal input terminal 106 are respectively electrically connected to present-stage scanning signal lines. The second scanning signal input terminal 105 is electrically connected to previous-stage scanning signal lines.

In summary, embodiments of the present disclosure improve picture quality of the display device by electrically connecting the reset unit in the pixel circuit to the control signal input terminal directly, and relieve leakage current in the circuit and the splash screen problem incurred by the leakage current by disposing the metal-oxide transistors in the compensation unit and the initialization unit of the pixel circuit.

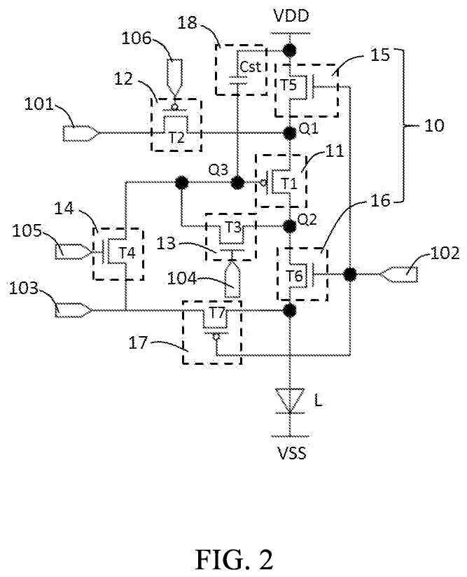

According to one embodiment of the present disclosure, FIG. 2 is a structural schematic diagram of a second embodiment of a pixel circuit provided by one embodiment of the present disclosure. In this embodiment, difference of this embodiment to the embodiment illustrated in FIG. 1 includes but is not limited to only including: the light emitting control unit 10 includes the metal-oxide transistor.

Specifically, in this embodiment, the pixel circuit includes the light emitting control unit 10, the reset unit 17, the compensation unit 13, and the initialization unit 14. The light emitting control unit 10 is disposed between the first power source signal input terminal VDD and the light emitting unit L. By controlling the electrically conducting state between the first power source signal input terminal VDD and the light emitting unit L, the control of the light emitting time of the light emitting unit L is realized. The light emitting control unit 10 is electrically connected to the control signal input terminal 102. A signal output from the control signal input terminal 102 controls the light emitting control unit 10 to turn on or to turn off. The reset unit 17 is disposed between the reset signal input terminal 103 and the light emitting unit L and is configured to control an electrically conducting state between the reset signal input terminal 103 and the light emitting unit L. The reset unit 17 is electrically connected to the control signal input terminal 102. The signal output from the control signal input terminal 102 controls the reset unit 17 to turn on or to turn off. The compensation unit 13 is electrically connected to the first scanning signal input terminal 104. The scanning signal output from the first scanning signal input terminal 104 controls the compensation unit 13 to turn on or to turn off. The initialization unit 14 is electrically connected to the second scanning signal input terminal 105. The scanning signal output from the second scanning signal input terminal 105 controls the initialization unit 14 to turn on or to turn off. The compensation unit 13 and the initialization unit 14 include the metal-oxide transistors.

Optionally, the light emitting control unit 10 includes the first light emitting control unit 15 and the second light emitting control unit 16, and the first light emitting control unit 15, the second light emitting control unit 16, and the reset unit 17 are electrically connected to the control signal input terminal 102. The first light emitting control unit 15 and the second light emitting control unit 16 include the metal-oxide transistors. The reset unit 17 includes the low-temperature polycrystalline-silicon transistor. By the configuration mentioned above, the reset unit 17 can be ensured to be in the turning off state when the first light emitting control unit 15 and the second light emitting control unit 16 are in the turning on state. On the contrary, the reset unit 17 is in the turning on state when the first light emitting control unit 15 and the second light emitting control unit 16 are in the turning off state, thereby making turning on time periods of the reset unit 17 always correspond to dark state periods of the light emitting unit L.

Furthermore, the pixel circuit further includes a data signal transmission unit 12, a driving unit 11, and a storage unit 18. The data signal transmission unit 12 is disposed between the data signal input terminal 101 and the light emitting control unit 10 to control electrically conducting state between the data signal input terminal 101 and the light emitting control unit 10. Optionally, the data signal transmission unit 12 is further electrically connected to the third scanning signal input terminal 106. The third scanning signal input terminal 106 outputs scanning signals to control the data signal transmission unit 12 to turn on or to turn off. The driving unit 11 is disposed between the first light emitting control unit 15 and the second light emitting control unit 16 to control electrically conducting state between the first light emitting control unit 15 and the second light emitting control unit 16. The storage unit 18 is disposed between the first power source signal input terminal VDD and the driving unit 11 to store a voltage state of a control terminal of the driving unit 11.

Optionally, the first light emitting control unit 15 includes a fifth transistor T5. A gate electrode of the fifth transistor T5 is electrically connected to the control signal input terminal 102. A source electrode of the fifth transistor T5 is electrically connected to the first power source signal input terminal VDD. A drain electrode of the fifth transistor T5 is electrically connected to a first node Q1. The fifth transistor T5 is the metal-oxide transistor.

Optionally, the second light emitting control unit 16 includes a sixth transistor T6. A gate electrode of the sixth transistor T6 is electrically connected to the control signal input terminal 102. A source electrode of the sixth transistor T6 is electrically connected to a second node Q2. A drain electrode of the sixth transistor T6 is electrically connected to the light emitting unit L. Another end of the light emitting unit L is electrically connected to a second power source signal input terminal VSS. The sixth transistor T6 is the metal-oxide transistor.

Optionally, the reset unit 17 includes a seventh transistor T7. A gate electrode of the seventh transistor T7 is electrically connected to the control signal input terminal 102. A source electrode of the seventh transistor T7 is electrically connected to the reset signal input terminal 103. A drain electrode of the seventh transistor T7 is electrically connected to the light emitting unit L. The seventh transistor T7 is the low-temperature polycrystalline-silicon transistor.

Optionally, the compensation unit 13 includes a third transistor T3. A gate electrode of the third transistor T3 is electrically connected to the first scanning signal input terminal 104. A source electrode of the third transistor T3 is electrically connected to the second node Q2. A drain electrode of the third transistor T3 is electrically connected to a third node Q3. The third transistor T3 is the metal-oxide transistor.

Optionally, the initialization unit 14 includes a fourth transistor T4. A gate electrode of the fourth transistor T4 is electrically connected to the second scanning signal input terminal 105. A source electrode of the fourth transistor T4 is electrically connected to the reset signal input terminal 103. A drain electrode of the fourth transistor T4 is electrically connected to the third node Q3. The fourth transistor T4 is the metal-oxide transistor.

Optionally, the data signal transmission unit 12 includes a second transistor T2. A gate electrode of the second transistor T2 is electrically connected to a third scanning signal input terminal 106. A source electrode of the second transistor T2 is electrically connected to the data signal input terminal 101. A drain electrode of the second transistor T2 is electrically connected to the first node Q1.

Optionally, the driving unit 11 includes a first transistor T1. A gate electrode of the first transistor T1 is electrically connected to the third node Q3. A source electrode of the first transistor T1 is electrically connected to the first node Q1. A drain electrode of the first transistor T1 is electrically connected to the second node Q2.

Optionally, the storage unit 18 includes a storage capacitor Cst. A first electrode of the storage capacitor Cst is electrically connected to the first power source signal input terminal VDD, and a second electrode of the storage capacitor Cst is electrically connected to the third node Q3. The storage capacitor Cst is configured to store a threshold voltage of the first transistor T1.

In summary, embodiments of the present disclosure improve picture quality of the display device by electrically connecting the reset unit in the pixel circuit to the control signal input terminal directly, and relieve leakage current in the circuit and the splash screen problem incurred by the leakage current by disposing the metal-oxide transistors in the compensation unit and the initialization unit of the pixel circuit.

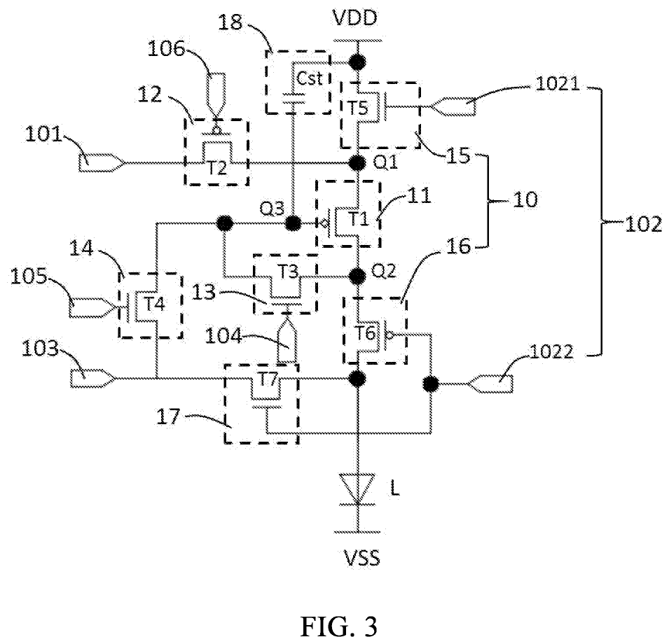

According to one embodiment of the present disclosure, FIG. 3 is a structural schematic diagram of a third embodiment of the pixel circuit provided by one embodiment of the present disclosure. In this embodiment, difference of this embodiment to the embodiment illustrated in FIG. 1 includes but is not limited to only including: the control signal input terminal 102 includes the first control signal input terminal 1021 and the second control signal input terminal 1022.

Specifically, in this embodiment, the pixel circuit includes the light emitting control unit 10, the reset unit 17, the compensation unit 13, and the initialization unit 14. The light emitting control unit 10 is disposed between the first power source signal input terminal VDD and the light emitting unit L. By controlling the electrically conducting state between the first power source signal input terminal VDD and the light emitting unit L, the control of the light emitting time of the light emitting unit L is realized. The light emitting control unit 10 is electrically connected to the control signal input terminal 102. A signal output from the control signal input terminal 102 controls the light emitting control unit 10 to turn on or to turn off. The reset unit 17 is disposed between the reset signal input terminal 103 and the light emitting unit L and is configured to control an electrically conducting state between the reset signal input terminal 103 and the light emitting unit L. The reset unit 17 is electrically connected to the control signal input terminal 102. The signal output from the control signal input terminal 102 controls the reset unit 17 to turn on or to turn off. The compensation unit 13 is electrically connected to the first scanning signal input terminal 104. The scanning signal output from the first scanning signal input terminal 104 controls the compensation unit 13 to turn on or to turn off. The initialization unit 14 is electrically connected to the second scanning signal input terminal 105. The scanning signal output from the second scanning signal input terminal 105 controls the initialization unit 14 to turn on or to turn off. The compensation unit 13 and the initialization unit 14 include the metal-oxide transistors.

Optionally, the light emitting control unit 10 includes the first light emitting control unit 15 and the second light emitting control unit 16. The control signal input terminal 102 includes the first control signal input terminal 1021 and the second control signal input terminal 1022. The first light emitting control unit 15 is electrically connected to the first control signal input terminal 1021, and the second light emitting control unit 16 and the reset unit 17 are electrically connected to the second control signal input terminal 1022. The first light emitting control unit 15 and the reset unit 17 include the metal-oxide transistors. The second light emitting control unit 16 includes the low-temperature polycrystalline-silicon transistor. By the configuration mentioned above, the reset unit 17 can be ensured to be in the turning off state when the second light emitting control unit 16 is in the turning on state. On the contrary, the reset unit 17 is in the turning on state when the second light emitting control unit 16 is in the turning off state, thereby making turning on time periods of the reset unit 17 always correspond to dark state periods of the light emitting unit L. Moreover, the first light emitting control unit 15 includes the metal-oxide transistor, which facilitates to reduce the leakage current in the pixel circuit.

Furthermore, the pixel circuit further includes a data signal transmission unit 12, a driving unit 11, and a storage unit 18. The data signal transmission unit 12 is disposed between the data signal input terminal 101 and the light emitting control unit 10 to control electrically conducting state between the data signal input terminal 101 and the light emitting control unit 10. Optionally, the data signal transmission unit 12 is further electrically connected to a third scanning signal input terminal 106. The third scanning signal input terminal 106 outputs scanning signals to control the data signal transmission unit 12 to turn on or to turn off. The driving unit 11 is disposed between the first light emitting control unit 15 and the second light emitting control unit 16 to control electrically conducting state between the first light emitting control unit 15 and the second light emitting control unit 16. The storage unit 18 is disposed between the first power source signal input terminal VDD and the driving unit 11 to store a voltage state of a control terminal of the driving unit 11.

Optionally, the first light emitting control unit 15 includes a fifth transistor T5. A gate electrode of the fifth transistor T5 is electrically connected to the first control signal input terminal 1021. A source electrode of the fifth transistor T5 is electrically connected to the first power source signal input terminal VDD. A drain electrode of the fifth transistor T5 is electrically connected to a first node Q1. The fifth transistor T5 is the metal-oxide transistor.

Optionally, the second light emitting control unit 16 includes a sixth transistor T6. A gate electrode of the sixth transistor T6 is electrically connected to the second control signal input terminal 1022. A source electrode of the sixth transistor T6 is electrically connected to a second node Q2. A drain electrode of the sixth transistor T6 is electrically connected to the light emitting unit L. Another end of the light emitting unit L is electrically connected to a second power source signal input terminal VSS. The fifth transistor T6 is the low-temperature polycrystalline-silicon transistor.

Optionally, the reset unit 17 includes a seventh transistor T7. A gate electrode of the seventh transistor T7 is electrically connected to the second control signal input terminal 1022. A source electrode of the seventh transistor T7 is electrically connected to the reset signal input terminal 103. A drain electrode of the seventh transistor T7 is electrically connected to the light emitting unit L. The seventh transistor T7 is the metal-oxide transistor.

Optionally, the compensation unit 13 includes a third transistor T3. A gate electrode of the third transistor T3 is electrically connected to the first scanning signal input terminal 104. A source electrode of the third transistor T3 is electrically connected to the second node Q2. A drain electrode of the third transistor T3 is electrically connected to a third node Q3. The third transistor T3 is the metal-oxide transistor.

Optionally, the initialization unit 14 includes a fourth transistor T4. A gate electrode of the fourth transistor T4 is electrically connected to the second scanning signal input terminal 105. A source electrode of the fourth transistor T4 is electrically connected to the reset signal input terminal 103. A drain electrode of the fourth transistor T4 is electrically connected to the third node Q3. The fourth transistor T4 is the metal-oxide transistor.

Optionally, the data signal transmission unit 12 includes a second transistor T2. A gate electrode of the second transistor T2 is electrically connected to a third scanning signal input terminal 106. A source electrode of the second transistor T2 is electrically connected to the data signal input terminal 101. A drain electrode of the second transistor T2 is electrically connected to the first node Q1.

Optionally, the driving unit 11 includes a first transistor T1. A gate electrode of the first transistor T1 is electrically connected to the third node Q3. A source electrode of the first transistor T1 is electrically connected to the first node Q1. A drain electrode of the first transistor T1 is electrically connected to the second node Q2.

Optionally, the storage unit 18 includes a storage capacitor Cst. A first electrode of the storage capacitor Cst is electrically connected to the first power source signal input terminal VDD, and a second electrode of the storage capacitor Cst is electrically connected to the third node Q3. The storage capacitor Cst is configured to store a threshold voltage of the first transistor T1.

In summary, embodiments of the present disclosure improve picture quality of the display device by electrically connecting the reset unit in the pixel circuit to the second control signal input terminal directly, and relieve leakage current in the circuit and the splash screen problem incurred by the leakage current by disposing the metal-oxide transistors in the compensation unit and the initialization unit of the pixel circuit.

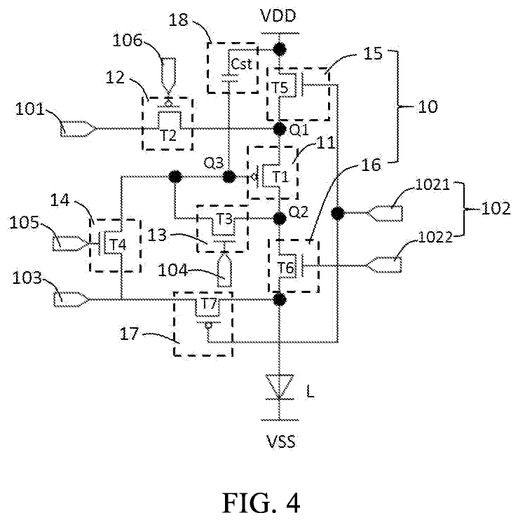

According to one embodiment of the present disclosure, FIG. 4 is a structural schematic diagram of a fourth embodiment of a pixel circuit provided by one embodiment of the present disclosure. In this embodiment, difference of this embodiment to the embodiment illustrated in FIG. 1 includes but is not limited to only including: the control signal input terminal 102 includes the first control signal input terminal 1021 and the second control signal input terminal 1022.

Specifically, in this embodiment, the pixel circuit includes the light emitting control unit 10, the reset unit 17, the compensation unit 13, and the initialization unit 14. The light emitting control unit 10 is disposed between the first power source signal input terminal VDD and the light emitting unit L. By controlling the electrically conducting state between the first power source signal input terminal VDD and the light emitting unit L, the control of the light emitting time of the light emitting unit L is realized. The light emitting control unit 10 is electrically connected to the control signal input terminal 102. A signal output from the control signal input terminal 102 controls the light emitting control unit 10 to turn on or to turn off. The reset unit 17 is disposed between the reset signal input terminal 103 and the light emitting unit L and is configured to control an electrically conducting state between the reset signal input terminal 103 and the light emitting unit L. The reset unit 17 is electrically connected to the control signal input terminal 102. The signal output from the control signal input terminal 102 controls the reset unit 17 to turn on or to turn off. The compensation unit 13 is electrically connected to the first scanning signal input terminal 104. The scanning signal output from the first scanning signal input terminal 104 controls the compensation unit 13 to turn on or to turn off. The initialization unit 14 is electrically connected to the second scanning signal input terminal 105. The scanning signal output from the second scanning signal input terminal 105 controls the initialization unit 14 to turn on or to turn off. The compensation unit 13 and the initialization unit 14 include the metal-oxide transistors.

Optionally, the light emitting control unit 10 includes the first light emitting control unit 15 and the second light emitting control unit 16. The control signal input terminal 102 includes the first control signal input terminal 1021 and the second control signal input terminal 1022. The first light emitting control unit 15 and the reset unit 17 are electrically connected to the first control signal input terminal 1021. The second light emitting control unit 16 is electrically connected to the second control signal input terminal 1022. The first light emitting control unit 15 and the second light emitting control unit 16 include the metal-oxide transistors. The reset unit 17 includes the low-temperature polycrystalline-silicon transistor. By the configuration mentioned above, the reset unit 17 can be ensured to be in the turning off state when the first light emitting control unit 15 is in the turning on state. On the contrary, the reset unit 17 is in the turning on state when the first light emitting control unit 15 is in the turning off state, thereby making turning on time periods of the reset unit 17 always correspond to dark state periods of the light emitting unit L. Moreover, the first light emitting control unit 15 and the second light emitting control unit 16 include the metal-oxide transistors, which facilitates to reduce the leakage current in the pixel circuit.

Furthermore, the pixel circuit further includes a data signal transmission unit 12, a driving unit 11, and a storage unit 18. The data signal transmission unit 12 is disposed between the data signal input terminal 101 and the light emitting control unit 10 to control electrically conducting state between the data signal input terminal 101 and the light emitting control unit 10. Optionally, the data signal transmission unit 12 is further electrically connected to a third scanning signal input terminal 106. The third scanning signal input terminal 106 outputs scanning signals to control the data signal transmission unit 12 to turn on or to turn off. The driving unit 11 is disposed between the first light emitting control unit 15 and the second light emitting control unit 16 to control electrically conducting state between the first light emitting control unit 15 and the second light emitting control unit 16. The storage unit 18 is disposed between the first power source signal input terminal VDD and the driving unit 11 to store a voltage state of a control terminal of the driving unit 11.

Optionally, the first light emitting control unit 15 includes a fifth transistor T5. A gate electrode of the fifth transistor T5 is electrically connected to the first control signal input terminal 1021. A source electrode of the fifth transistor T5 is electrically connected to the first power source signal input terminal VDD. A drain electrode of the fifth transistor T5 is electrically connected to a first node Q1. The fifth transistor T5 is the metal-oxide transistor.

Optionally, the second light emitting control unit 16 includes a sixth transistor T6. A gate electrode of the sixth transistor T6 is electrically connected to the second control signal input terminal 1022. A source electrode of the sixth transistor T6 is electrically connected to a second node Q2. A drain electrode of the sixth transistor T6 is electrically connected to the light emitting unit L. Another end of the light emitting unit L is electrically connected to a second power source signal input terminal VSS. The sixth transistor T6 is the metal-oxide transistor.

Optionally, the reset unit 17 includes a seventh transistor T7. A gate electrode of the seventh transistor T7 is electrically connected to the first control signal input terminal 1021. A source electrode of the seventh transistor T7 is electrically connected to the reset signal input terminal 103. A drain electrode of the seventh transistor T7 is electrically connected to the light emitting unit L. The seventh transistor T7 is the low-temperature polycrystalline-silicon transistor.

Optionally, the compensation unit 13 includes a third transistor T3. A gate electrode of the third transistor T3 is electrically connected to the first scanning signal input terminal 104. A source electrode of the third transistor T3 is electrically connected to the second node Q2. A drain electrode of the third transistor T3 is electrically connected to a third node Q3. The third transistor T3 is the metal-oxide transistor.

Optionally, the initialization unit 14 includes a fourth transistor T4. A gate electrode of the fourth transistor T4 is electrically connected to the second scanning signal input terminal 105. A source electrode of the fourth transistor T4 is electrically connected to the reset signal input terminal 103. A drain electrode of the fourth transistor T4 is electrically connected to the third node Q3. The fourth transistor T4 is the metal-oxide transistor.

Optionally, the data signal transmission unit 12 includes a second transistor T2. A gate electrode of the second transistor T2 is electrically connected to a third scanning signal input terminal 106. A source electrode of the second transistor T2 is electrically connected to the data signal input terminal 101. A drain electrode of the second transistor T2 is electrically connected to the first node Q1.

Optionally, the driving unit 11 includes a first transistor T1. A gate electrode of the first transistor T1 is electrically connected to the third node Q3. A source electrode of the first transistor T1 is electrically connected to the first node Q1. A drain electrode of the first transistor T1 is electrically connected to the second node Q2.

Optionally, the storage unit 18 includes a storage capacitor Cst. A first electrode of the storage capacitor Cst is electrically connected to the first power source signal input terminal VDD, and a second electrode of the storage capacitor Cst is electrically connected to the third node Q3. The storage capacitor Cst is configured to store a threshold voltage of the first transistor T1.

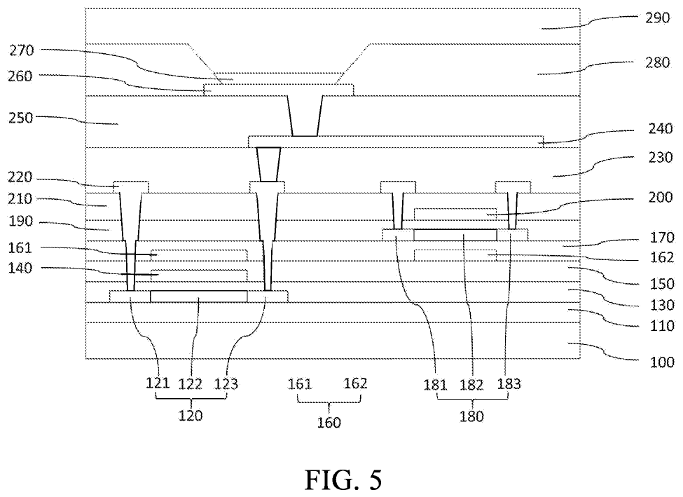

Optionally, the pixel circuit provided by the embodiments of the present disclosure can be applied in pixel driving of the organic light emitting diode display device. In the sectional structural schematic diagram of the organic light emitting diode display device including the low-temperature polycrystalline-silicon transistor and the metal-oxide transistor illustrated in FIG. 5, the substrate host 100 can include an insulating material, which can be glass, quartz, ceramics, or plastic. A buffer layer 110 is arranged on the substrate host 100, and for example, the buffer layer 110 can include various organic materials or inorganic materials. A first semiconductor layer 120 is arranged on the buffer layer 110, and a base material of the semiconductor can be an N-type or P-type polycrystalline silicon semiconductor. A first gate insulation layer material 130 is arranged on the first semiconductor layer 120, and a material thereof can include silicon nitride or silica. A material of a first gate electrode 140 can be a metal material of Mo. The first semiconductor layer 120 can be divided into a source electrode 121, a channel section 122, and a drain electrode 123. The first gate electrode 140 and the source electrode 121, the channel 122, and the drain electrode 123 constitute a gate electrode, a source electrode, and a drain electrode of a low-temperature polycrystalline-silicon transistor. A second insulation layer 150 is arranged on the first gate electrode 140, and a material thereof can include silicon nitride or silica. A material of a second gate electrode 160 can be a metal of Mo, and a part 161 of the second gate electrode and the first gate electrode 140 constitute top and bottom electrodes of the storage capacitor in the pixel circuit. A third insulation layer 170 covers on the second gate electrode 160, and a material thereof can include silicon nitride or silica. A second semiconductor layer 180 is arranged on the third insulation layer 170, and its material is a semiconductor with oxide. The second semiconductor layer 180 can be divided into a source electrode 181, a channel 182, and a drain electrode 183. A fourth gate insulation layer 190 is arranged on the second semiconductor 180, and a material thereof can include silicon nitride or silica. A material of a third gate electrode 200 can be a metal of Mo. The third gate electrode 200 and the source electrode 181, the channel 182, and the drain electrode 183 of the second semiconductor layer form a gate electrode, a source electrode, and a drain electrode of the metal-oxide transistor. Wherein the part 162 of the second gate electrode constitutes a section of the bottom gate electrode of the metal-oxide transistor. A fifth insulating layer 210 is arranged on the third gate electrode 200, and a material thereof can include silicon nitride or silica. A first metal conductive material 220 is arranged on the fifth insulating layer 210, and gold, silver, copper, lithium, potassium, magnesium, aluminum, zinc, or combination thereof is used as its material. The first metal conductive material 220 is electrically connected to the gate electrodes, the source electrodes, and the drain electrodes of the low-temperature polycrystalline-silicon transistor and the metal-oxide transistor through openings on the insulating layer below. A sixth insulating layer 230 is arranged on the first metal conductive material 220, and an organic material, an inorganic material, or mixture thereof can be used as its material. A second metal conductive material 240 is arranged on the sixth insulating layer 230, and gold, silver, copper, lithium, potassium, magnesium, aluminum, zinc, or combination thereof is used as its material. The first metal conductive material 240 is electrically connected to the first metal conductive material 220 through openings of the sixth insulating layer 230. A seventh insulating layer 250 is arranged on the second metal conductive material 240, and an organic material, an inorganic material, or mixture thereof can be used as its material. An anode 260 is arranged on the seventh insulating layer 250, and its material is a combination of ITO and Ag. The anode 260 is electrically connected to the second metal conductive material 240 through an opening of the seventh insulating layer 250 below. A pixel definition layer 280 is arranged on the anode 260. A shape of an opening of the pixel definition layer 280 is consistent with a pattern of subpixels of the display device. An organic light emitting material 270 contacts with the anode 260 below through the opening of the pixel definition layer 280. An encapsulation layer 290 is on a top side, and its material includes a combination of an organic material and an inorganic material.

In summary, embodiments of the present disclosure improve picture quality of the display device by electrically connecting the reset unit in the pixel circuit to the first control signal input terminal directly, and relieve leakage current in the circuit and the splash screen problem incurred by the leakage current by disposing the metal-oxide transistors in the compensation unit and the initialization unit of the pixel circuit.

One embodiment of the present disclosure further provides a display device. The display device includes the pixel circuit of any embodiment mentioned above. It should be understood that the display device performs better picture quality in the dark state due to inclusion of the pixel circuit. Furthermore, compared to the prior art, the leakage current of an inner circuit of the display device and the splash screen problem incurred by the leakage current obtain significant relievement.

It should be noted that although the present disclosure has disclosed the specific embodiments as above, the above-mentioned embodiments are not to limit to the present disclosure. A person skilled in the art can make any change and modification; therefore, the scope of protection of the present disclosure is subject to the scope defined by the claims.

1. A pixel circuit, comprising:
a light emitting control unit disposed between a first power source signal input terminal and a light emitting unit and electrically connected to a control signal input terminal;
a reset unit disposed between a reset signal input terminal and the light emitting unit and electrically connected to the control signal input terminal;
a compensation unit electrically connected to a first scanning signal input terminal; and
an initialization unit electrically connected to a second scanning signal input terminal,
wherein the compensation unit and the initialization unit comprise metal-oxide transistors.

2. The pixel circuit as claimed in claim 1, wherein a control terminal of the light emitting control unit is electrically connected to the control signal input terminal and realizes switch between turning on and turning off states of the light emitting control unit under effect of signals output from the control signal input terminal.

3. The pixel circuit as claimed in claim 1, wherein a control terminal of the reset unit is electrically connected to the control signal input terminal and realizes switch between turning on and turning off states of the reset unit under effect of signals output from the control signal input terminal.

4. The pixel circuit as claimed in claim 1, wherein the reset unit comprises the metal-oxide transistors.

5. The pixel circuit as claimed in claim 4, wherein the light emitting control unit comprises low-temperature polycrystalline-silicon transistors.

6. The pixel circuit as claimed in claim 1, wherein the light emitting control unit comprises a first light emitting control unit and a second light emitting control unit, and the first light emitting control unit and the second light emitting control unit are electrically connected to the control signal input terminal.

7. The pixel circuit as claimed in claim 6, wherein the first light emitting control unit and the second light emitting control unit comprise the metal-oxide transistors.

8. The pixel circuit as claimed in claim 7, wherein the reset unit comprises low-temperature polycrystalline-silicon transistors.

9. The pixel circuit as claimed in claim 6, wherein the control signal input terminal comprises a first control signal input terminal and a second control signal input terminal.

10. The pixel circuit as claimed in claim 9, wherein the first light emitting control unit is electrically connected to the first control signal input terminal, and the second light emitting control unit and the reset unit are electrically connected to the second control signal input terminal.

11. The pixel circuit as claimed in claim 10, wherein the first light emitting control unit and the reset unit comprise the metal-oxide transistors.

12. The pixel circuit as claimed in claim 11, wherein the second light emitting control unit comprises low-temperature polycrystalline-silicon transistors.

13. The pixel circuit as claimed in claim 9, wherein the first light emitting control unit and the reset unit are electrically connected to the first control signal input terminal, and the second light emitting control unit is electrically connected to the second control signal input terminal.

14. The pixel circuit as claimed in claim 13, wherein the first light emitting control unit and the second light emitting control unit comprise the metal-oxide transistors.

15. The pixel circuit as claimed in claim 14, wherein the reset unit comprises low-temperature polycrystalline-silicon transistors.

16. The pixel circuit as claimed in claim 6, wherein the pixel circuit further comprises:
a data signal transmission unit disposed between a data signal input terminal and the light emitting control unit;
a driving unit disposed between the first light emitting control unit and the second light emitting control unit;
a storage unit disposed between the first power source signal input terminal and the driving unit.

17. The pixel circuit as claimed in claim 16, wherein
the pixel circuit comprises a first transistor, a second transistor, a third transistor, a fourth transistor, a fifth transistor, a sixth transistor, and a seventh transistor,
the first light emitting control unit comprises the fifth transistor, a gate electrode of the fifth transistor is electrically connected to the control signal input terminal, a source electrode of the fifth transistor is electrically connected to the first power source signal input terminal, and a drain electrode of the fifth transistor is electrically connected to a first node;
the second light emitting control unit comprises the sixth transistor, a gate electrode of the sixth transistor is electrically connected to the control signal input terminal, a source electrode of the sixth transistor is electrically connected to a second node, and a drain electrode of the sixth transistor is electrically connected to the light emitting unit;
the reset unit comprises the seventh transistor, a gate electrode of the seventh transistor is electrically connected to the control signal input terminal, a source electrode of the seventh transistor is electrically connected to the reset signal input terminal, and a drain electrode of the seventh transistor is electrically connected to the light emitting unit;
the compensation unit comprises the third transistor, a gate electrode of the third transistor is electrically connected to the first scanning signal input terminal, a source electrode of the third transistor is electrically connected to the second node, and a drain electrode of the third transistor is electrically connected to a third node;
the initialization unit comprises the fourth transistor, a gate electrode of the fourth transistor is electrically connected to the second scanning signal input terminal, a source electrode of the fourth transistor is electrically connected to the reset signal input terminal, and a drain electrode of the fourth transistor is electrically connected to the third node;
the data signal transmission unit comprises the second transistor, a gate electrode of the second transistor is electrically connected to a third scanning signal input terminal, a source electrode of the second transistor is electrically connected to the data signal input terminal, and a drain electrode of the second transistor is electrically connected to the first node;
the driving unit comprises the first transistor, a gate electrode of the first transistor is electrically connected to the third node, a source electrode of the first transistor is electrically connected to the first node, and a drain electrode of the first transistor is electrically connected to the second node; and
the storage unit comprises a storage capacitor, a first electrode of the storage capacitor is electrically connected to the first power source signal input terminal, and a second electrode of the storage capacitor is electrically connected to the third node.

18. A display device, comprising a pixel circuit, wherein the pixel circuit comprises:
a light emitting control unit disposed between a first power source signal input terminal and a light emitting unit and electrically connected to a control signal input terminal;
a reset unit disposed between a reset signal input terminal and the light emitting unit and electrically connected to the control signal input terminal;
a compensation unit electrically connected to a first scanning signal input terminal; and
an initialization unit electrically connected to a second scanning signal input terminal,
wherein the compensation unit and the initialization unit comprise metal-oxide transistors.

19. The display device as claimed in claim 18, wherein the reset unit comprises the metal-oxide transistors, and the light emitting control unit comprises low-temperature polycrystalline-silicon transistors.

20. The display device as claimed in claim 18, wherein the reset unit comprises low-temperature polycrystalline-silicon transistors, and the light emitting control unit comprises the metal-oxide transistors.
